(19) United States
(12) Patent Application Publication
(10) Pub. No.: US 2024/0347798 A1
(43) Pub. Date: Oct. 17, 2024

(54) COMBINED LIQUID ELECTROLYTE AND TEMPERATURE SENSOR

(71) Applicant: Enatel, Christchurch (NZ)

(72) Inventor: Anton Clark, Christchurch (NZ)

(21) Appl. No.: 18/682,367

(22) PCT Filed: Aug. 11, 2021
(86) PCT No.: PCT/NZ2021/050127

§ 371 Date: Feb. 8, 2024

(51) Int. Cl. H01M 10/48; G01K 1/024; G01K 1/14; G01K 1/16; G01K 3/00; H01M 10/06; H01M 10/42

(52) U.S. Cl. CPC H01M 10/486; G01K 1/024; G01K 1/14; G01K 1/16; G01K 3/005; H01M 10/06; H01M 10/425; H01M 10/484

(57) ABSTRACT

A temperature and electrolyte sensor for a battery includes a probe that is electrically conductive and thermally conductive and configured to be disposed in a liquid electrolyte of the battery. The sensor further includes a thermal coupler coupled to the probe, a temperature determination circuit electrically thermally coupled to the probe and configured to output a signal indicative of a temperature of the probe, and a fluid detection circuit electrically coupled to the thermal coupler and configured to output a signal indicative of a presence of the liquid on the probe. The temperature determination circuit and fluid detection circuit may be disposed in a housing of the sensor, and the probe may extend from the housing.

### TECHNICAL FIELD

This disclosure generally relates to a liquid electrolyte and temperature sensor, such as a liquid electrolyte and temperature sensor for a battery.

### BACKGROUND

Known battery monitoring systems may include a temperature sensor disposed on the exterior of a battery cell and/or may include a sensor inside of the battery cell to determine a level of the liquid electrolyte.

### SUMMARY

In a first aspect of the present disclosure, a sensor is disclosed. The sensor includes a probe that is electrically conductive and thermally conductive and configured to be disposed in an electrically-conductive liquid, a thermal coupler coupled to the probe, a temperature determination circuit electrically coupled to the probe and configured to output a signal indicative of a temperature of the probe, and a fluid detection circuit electrically coupled to the thermal coupler and configured to output a signal indicative of a presence of the liquid on the probe.

In an embodiment of the first aspect, the sensor further includes a printed circuit board (PCB), wherein the temperature determination circuit and the fluid detection circuit are on the PCB. In a further embodiment of the first aspect, the sensor further includes an overmolded body, wherein the probe extends from the body, wherein the PCB is disposed within the body.

In an embodiment of the first aspect, the thermal coupler includes a sleeve crimped to the probe. In a further embodiment of the first aspect, the sleeve includes copper.

In an embodiment of the first aspect, the temperature detection circuit is electrically isolated from the fluid detection circuit.

In a second aspect of the present disclosure, a battery is provided. The battery includes a battery cell comprising a cell body and a liquid electrolyte disposed in the cell body, the cell body defining an aperture. The battery further includes a sensor, the sensor including a probe that is electrically conductive and thermally conductive, the probe extending through the aperture and configured to be disposed in the liquid electrolyte, a thermal coupler coupled to the probe, a temperature determination circuit electrically coupled to the probe and configured to output a signal indicative of a temperature of the probe, and a fluid detection circuit electrically coupled to the thermal coupler and configured to output a signal indicative of a presence of the liquid electrolyte on the probe.

In an embodiment of the second aspect, the sensor further includes a printed circuit board (PCB), wherein the temperature determination circuit and the fluid detection circuit are on the PCB. In a further embodiment of the second aspect, the sensor further includes an overmolded body, wherein the probe extends from the body, wherein the PCB is disposed within the body.

In an embodiment of the second aspect, the thermal coupler includes a sleeve crimped to the probe. In a further embodiment of the second aspect, the sleeve includes copper.

In an embodiment of the second aspect, the temperature detection circuit is electrically isolated from the fluid detection circuit.

In an embodiment of the second aspect, the sensor further includes a gasket configured to form a fluid-tight seal with the aperture.

In an embodiment of the second aspect, the battery cell is a lead-acid cell.

In a third aspect of the present disclosure, a battery system is provided. The battery system includes a battery cell comprising a cell body and a liquid electrolyte disposed in the cell body, the cell body defining an aperture. The battery system further includes a sensor, the sensor including a probe that is electrically conductive and thermally conductive, the probe extending through the aperture and configured to be disposed in the liquid electrolyte, a thermal coupler coupled to the probe, a temperature determination circuit electrically coupled to the probe and configured to output a signal indicative of a temperature of the probe, and a fluid detection circuit electrically coupled to the thermal coupler and configured to output a signal indicative of a presence of the liquid electrolyte on the probe. The battery system further includes an electronic battery monitor in electronic communication with the fluid detection circuit and with the temperature determination circuit, the battery monitor configured to determine a temperature of the probe according to the output of the temperature detection circuit, determine a presence of liquid on the probe according to the output of the fluid detection circuit, and output an alert when the battery monitor determines an absence of fluid on the probe or that the temperature of the probe exceeds a threshold.

In an embodiment of the third aspect, the electronic battery monitor includes a display, a speaker, or a display and a speaker, configured to output the alert.

In an embodiment of the third aspect, the battery cell is a lead-acid cell.

In an embodiment of the third aspect, the sensor further includes a printed circuit board (PCB), wherein the temperature determination circuit and the fluid detection circuit are on the PCB. In a further embodiment of the third aspect, the sensor further includes an overmolded body, wherein the probe extends from the body, wherein the PCB is disposed within the body.

In an embodiment of the third aspect, the thermal coupler includes a copper sleeve crimped to the probe.

### BRIEF DESCRIPTION OF THE DRAWINGS

FIG. 1 is an isometric view of a combined temperature and electrolyte sensor.

FIG. 2 is an enlarged side view of a portion of the combined temperature and electrolyte sensor of FIG. 1.

FIG. 3 is a top view of the combined temperature and electrolyte sensor of FIG. 1.

FIG. 4 is an exploded view of the combined temperature and electrolyte sensor of FIG. 1.

FIG. 5 is a cross-sectional view of a portion of the combined temperature and electrolyte sensor of FIG. 1, taken along line 5-5 in FIG. 3.

FIG. 6 is a diagrammatic view of a battery monitoring system including a plurality of combined temperature and electrolyte sensors.

FIG. 7 is a flow chart illustrating an example method of assembling a battery cell to include a combined temperature and electrolyte sensor.

### DETAILED DESCRIPTION

Although known battery monitoring systems may include a temperature sensor and/or electrolyte sensor, such sensors are provided separate from each other. As a result, to assemble a battery cell that includes both sensors, each sensor must be attached or otherwise coupled to the battery cell separately from the other sensor. Furthermore, temperature sensors are typically provided outside of the battery cell, where a temperature reading from inside the battery cell may be more accurate. Accordingly, a combined temperature and electrolyte sensor that reads the temperature and electrolyte level from a single probe placed within the battery cell may simplify battery assembly and improve temperature monitoring accuracy.

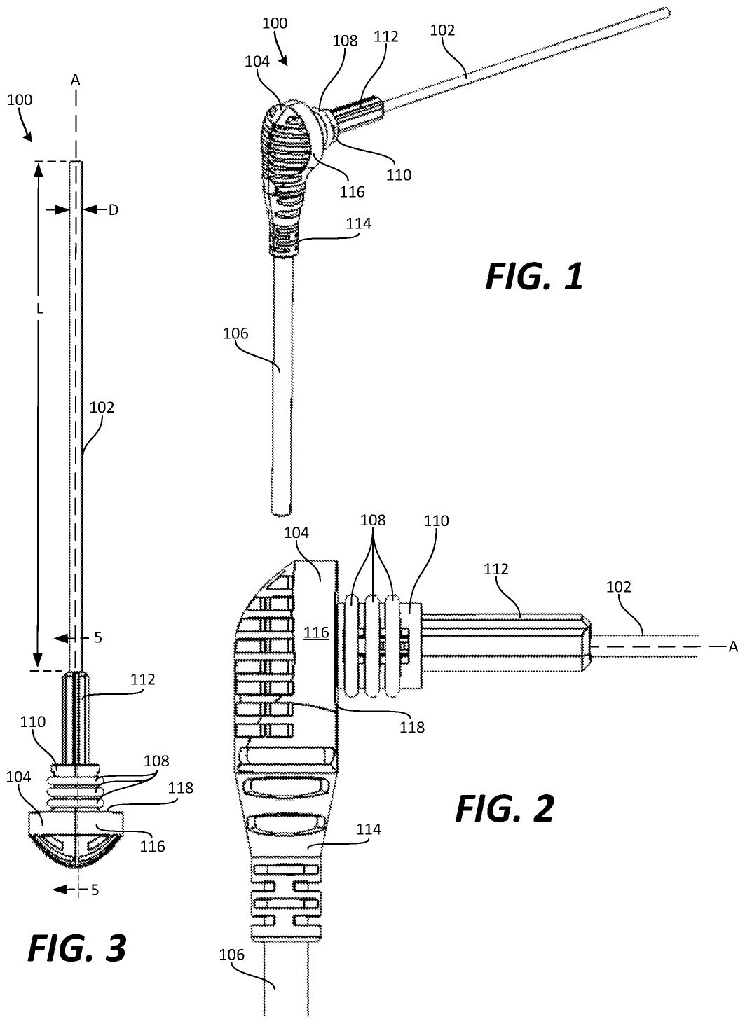

Referring to the drawings, wherein like reference numerals refer to the same or similar features in the various views, FIGS. 1-3 illustrate an example combined temperature and electrolyte sensor 100. The sensor 100 may include a probe 102, a body 104, a communications cable 106, one or more gaskets 108, and a body coupler 110.

The probe 102 may be a generally cylindrical probe that is electrically-conductive and thermally conductive. The probe may define a length L and a diameter D and may be radially symmetric about an axis A, in some embodiments. The probe 102 may be solid (e.g., lacking any hollows or apertures) over the majority of its length L, in some embodiments. The probe 102 may be formed of one or more electrically-conductive and thermally-conductive materials capable of minimal corrosion in a liquid electrolyte of a battery. For example, in some embodiments, the probe 102 may be formed of an austenitic stainless steel.

The probe 102 may have a length L appropriate for a desired application. In some embodiments, the probe 102 may be manufactured to a length that is longer than desired for intended applications, and the probe may be trimmed to a desired length L at the time of assembly with a battery or other device to be monitored.

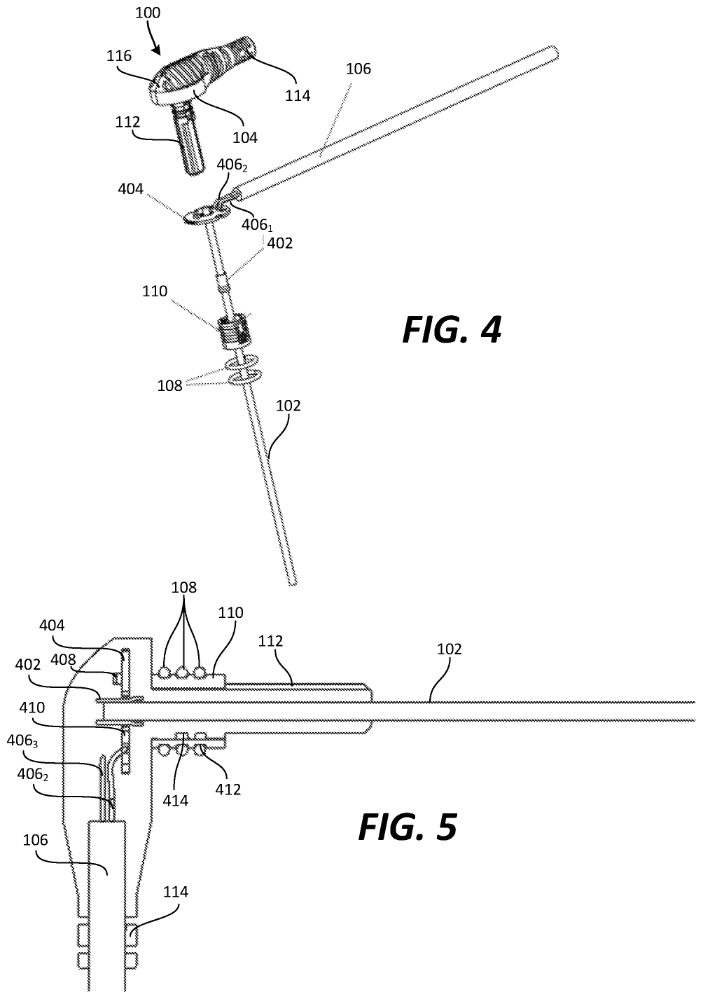

The body 104 may include an overmolded polymer, in some embodiments. The body 104 may define a first coupling portion 112 for the probe 102 and a second coupling portion 114 for the communications cable 106. Each coupling portion 112, 114 may include a respective passageway that is sized and shaped for friction fit with the probe 102 or communications cable 106. The body 104 may further include a main body portion 116 that is sized and shaped to contain and protect one or more electronic components, as will be described with respect to FIGS. 4 and 5 below. The main body portion 116 may include a substantially planar surface 118 adjacent to the first coupling portion 112 that is configured to be flush with a battery cell body when the probe 102 is inserted into the battery cell. The plane of the planar surface 118 may be substantially perpendicular to a central axis A of the probe 102, in some embodiments. The body 104 may protect the assembly from moisture, corrosion and mechanical damage and may provide insulation from other conductive parts, in embodiments.

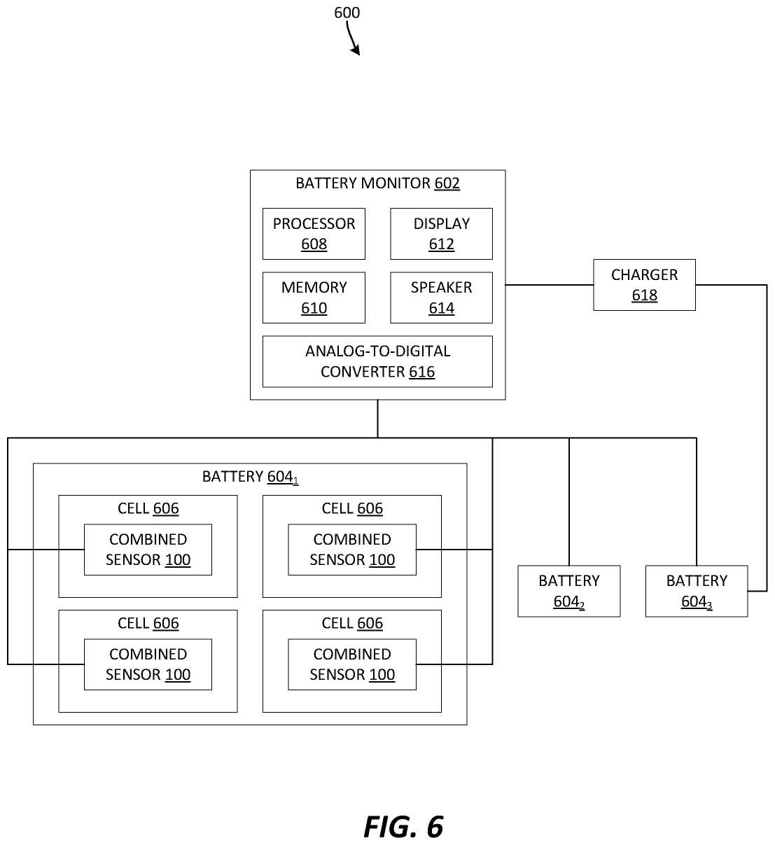

The communications cable 106 may enclose and secure one or more communication lines that carry an output from the sensor 100 to a battery monitor (e.g., as will be described in conjunction with FIG. 6). The communications cable 106 may additionally or alternatively enclose and secure one or more communication lines that connect electronics of the sensor 100 to an external voltage or temperature source as a reference for use by the sensor 100. The communications cable 106 may be friction fit and/or secured with adhesive or other coupling in the second coupling portion 114.

The body coupler 110 may be provided on the first coupling portion 112 and may have a size (e.g., diameter) appropriate for a desired aperture into which the probe 102 is to be inserted, so as to create a fluid-tight seal in the aperture in conjunction with the gaskets 108. In some embodiments, the body coupler 110 may be made from the same or a similar polymer material as the sensor body 104. The body coupler 110 may be removable from the sensor 100 and replaced with a different body coupler of a different size as needed for a desired application.

The gaskets 108 may be provided on the first coupling portion 112 and/or on the body coupler 110 to create a fluid-tight fit of the probe 102 in an aperture, such as the aperture of a battery cell. As illustrated, in some embodiments, three O-rings may be provided along the first coupling portion 112 and/or along the body coupler 110. In other embodiments, a different quantity of O-rings may be provided.

FIG. 4 is an exploded view of the sensor 100, and FIG. 5 is a cross-sectional view of a portion of the sensor 100, taken along line 5-5 in FIG. 3. Referring to FIGS. 4 and 5, the sensor 100 may further include a thermal coupler 402, a printed circuit board (PCB) 404 that includes a temperature determination circuit 408 and a liquid detection circuit 410, and one or more signal wires 406 (three such signal wires 4061, 4062, 4063 are shown).

The thermal coupler 402 may be a thermally-conductive and electrically-conductive component placed on the probe 102 for providing a thermal and electrical interface to one or more circuits. The thermal coupler 402 may be a sleeve surrounding the entire circumference of the probe 102, in some embodiments. The thermal coupler 402 may be crimped to the probe 102, in some embodiments. The thermal coupler 402 may be or may include copper, in some embodiments.

The PCB 404 may be disposed on and may be in thermal and electrical contact with the thermal coupler 402. Accordingly, the one or more circuits on the PCB 404 may be able to read a temperature and/or electrical potential present on the probe 102 through the thermal coupler 402. In some embodiments, the PCB 404 may be a generally circular PCB with a central aperture through which the probe 102 and the thermal coupler 402 extend. The thermal coupler 402 may be soldered to the PCB 404, in some embodiments. The thermal coupler may be provided as a thermal and electrical interface between the probe 102 and the PCB 404 because, in some embodiments, the material of the probe 102 may not be amenable to a soldered or other direct coupling with the PCB 404. For example, in embodiments in which the probe 102 is made from a stainless steel, the probe may not be solderable.

The temperature determination circuit 408 may be configured to determine a quantitative value of the temperature on the probe 102, in some embodiments. The temperature determination circuit 408 may include a thermistor that is thermally coupled to the thermal coupler 402, in some embodiments, such as by being disposed adjacent to the soldering point of the PCB 404 to the thermal coupler 402. The temperature determination circuit 408 may be configured to output an analog or digital signal that is indicative of the temperature of the probe 102 (and therefore of the temperature of the battery or other device into which the probe is inserted). In some embodiments, the temperature determination circuit 408 may include a thermistor, and a current may be driven through the thermistor, with an input current provided through signal wire 4061 and output current through signal wire 4062, and the voltage drop across the thermistor may be read by an external computing device (such as a battery monitor) and interpreted according to the thermistor's known resistance profile to determine the temperature of the probe. In such an embodiment, the output current may be an analog signal that is indicative of the temperature of the probe 102. In other embodiments, the temperature determination circuit 408 may include a thermocouple or silicon temperature sensor, both of which may also output an analog voltage indicative of temperature. In some embodiments, the temperature determination circuit 408 may include an analog-to-digital (A/D) converter, and the temperature determination circuit 408 may output a digital signal.

The liquid detection circuit 410 may be configured to determine whether or not liquid is present on the probe 102, and therefore whether or not the battery cell or other device into which the probe is inserted includes a liquid that covers at least a portion of the probe. In some embodiments, the liquid detection circuit 410 may determine a voltage between the probe 102 and a reference, such as a component of the battery (e.g., a negative terminal of the cell). That voltage may be compared to a threshold to determine if the probe is in contact with the liquid electrolyte of the battery or if it is in contact with air. The comparison may take place in the liquid detection circuit 410 or in an external battery monitor or other computing device. The liquid detection circuit 410 may output a Boolean value, in some embodiments. In other embodiments, the liquid detection circuit 410 may output the voltage detected between the probe and the reference. In still other embodiments, the liquid detection circuit 410 may output the potential on the probe for determination of a voltage with respect to a reference and comparison of that voltage to a threshold outside of the sensor 100. In an embodiment, the third signal wire 4063 may carry the potential on the probe 102.

In some embodiments, the temperature determination circuit 408 may be electrically isolated from the liquid detection circuit 410. For example, in some embodiments, the liquid detection circuit may be electrically coupled to the thermal coupler 402, whereas the temperature determination circuit 408 may not be electrically coupled to the thermal coupler 402 and may instead include one or more components that are thermally coupled to the thermal coupler 402 by proximity to the thermal coupler 402.

The signal wires 406 may carry the output of the temperature determination circuit 408 and/or the liquid detection circuit 410 to a computing device outside of the sensor 100, in some embodiments. For example, the signal wires may provide an electrical communication path between the sensor 100 and a battery monitor, in some embodiments. Additionally or alternatively, the signal wires may carry a reference potential from outside the sensor to the PCB 404 for determination of a voltage on the probe 102, as described above. Accordingly, although three signal wires 4061, 4062, 4063 are illustrated, more or fewer signal wires 406 may be provided in different embodiments.

In some embodiments, the body coupler 110 may define one or more circumferential grooves 412 (one of which is designated in FIG. 5) to retain respective O-rings. Similarly, the first coupling portion 112 may include one or more circumferential grooves 414 (one of which is designated in FIG. 5) to retain respective O-rings in implementations in which the body coupler 110 is not used. Accordingly, in some embodiments, the body coupler 110 may be used to fit the probe 102 to a relatively larger aperture, thereby enabling a single probe size to be functional with a wide variety of aperture sizes with an appropriately-sized body coupler 110, and the body coupler 110 may be omitted where the aperture is sized to fit the first coupling portion 112 directly.

FIG. 6 is a diagrammatic view of an example battery monitoring system 600. The system 600 may include a battery monitor 602 and one or more batteries 604, each having one or more battery cells 606 and one or more combined temperature and electrolyte sensors 100 disposed in respective battery cells. In the illustrated embodiment, three batteries 604 are included, and each battery 604 includes four cells 606 (the cells of the second and third batteries 6042, 6043 are omitted for visual clarity; the second and third batteries 6042, 6043 may be identical to the first battery 6041 or may similarly include a respective plurality of cells, each with a sensor 100). Each sensor 100 may be in electronic communication with the battery monitor 602. The battery monitor 602 may be in electronic communication with one or more batteries and/or battery cells (e.g., sensors 100 of such batteries or cells) and may monitor the status of the one or more batteries 604 and/or battery cells 606 for certain conditions. For example, the battery monitor 602 may monitor each cell 606 for a low-electrolyte condition according to the output of a liquid detection circuit of each sensor 100. If a low electrolyte condition is detected (e.g., the output of a liquid detection circuit indicates that the probe of the sensor is not in contact with a liquid), the battery monitor 602 may output an alert. In another example, the battery monitor 602 may monitor each cell 606 for a high-temperature or low-temperature condition according to the output of a temperature determination circuit of each sensor 100. If a high-temperature or low-temperature condition is detected, the battery monitor 602 may output an alert.

In some embodiments, a battery monitor 602 may be coupled to a single sensor 100 disposed in a selected one of multiple battery cells 606 in a battery 604, with a separate battery monitor 602 provided for each battery 604. In such embodiments, it may be assumed that the cells in a given battery have a similar temperature and electrolyte level. In other embodiments, multiple sensors 100 may be provided per battery, and a battery monitor 602 may monitor multiple cells and/or multiple batteries.

The battery monitor 602 may include a processor 608 and a non-transitory, computer-readable memory 610. The memory 610 may contain instructions that, when executed by the processor 608, cause the processor 608 to perform one or more of the functions of the battery monitor 602 described herein, among other functions. The battery monitor may further include an analog-to-digital converter 616 that receives analog signals (e.g., an output current from a temperature determination circuit and a potential from a liquid detection circuit) from one or more sensors 100 and outputs digital signals for processing by the processor 608.

The battery monitor 602 may further include a display 612 and a speaker 614, in some embodiments. The battery monitor 602 may output one or more visual alerts through the display 612 and/or one or more audible alerts through the speaker 614. In some embodiments, the display may include a multi-color LED, and the alert may include a specific color of the LED.

In some embodiments, the battery monitor 602 may also be in electronic communication with a charger 618 coupled to one or more of the batteries 604. In FIG. 6, the charger 618 is shown coupled to battery 6043. The battery monitor 602 may, in addition to or instead of outputting an alert, alter operation of the charger 618 when a high temperature or low electrolyte condition is detected in the battery 6043 coupled to the charger. Still further, in some embodiments, the battery monitor 602 may be configured to instruct the battery charger 618 to control the conditions of a charge (e.g., a voltage set point) according to the temperature of the battery 6043.

In some embodiments, the battery monitor 602 may be hard-wired to each sensor 100. In other embodiments, the battery monitor 602 may receive the output of one or more sensors 100 via wireless communications.

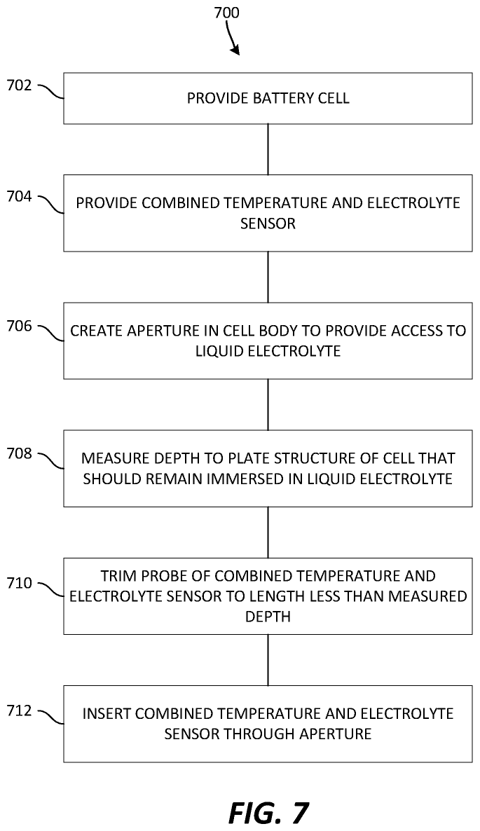

FIG. 7 is a flow chart illustrating an example method 700 of assembling a battery cell. The method may be performed to assemble a battery cell 606, in some embodiments.

The method 700 may include, at block 702, providing a battery cell. The battery cell may be a lead-acid cell or another battery cell type with a liquid electrolyte. The battery cell may already be incorporated into, or may be intended to later be incorporated into, a multi-cell battery 604.

The method 700 may further include, at block 704, providing a combined temperature and liquid electrolyte sensor. The sensor may be the sensor 100, in some embodiments.

The method 706 may further include, at block 706, creating an aperture through a body of the battery cell to provide access to the liquid electrolyte of the cell. The aperture may be generally circular, in some embodiments, so that a fluid-tight seal can be formed by the sensor in the aperture. The aperture may be created in the top of the cell body, in some embodiments, such that the liquid electrolyte will progressively cover less of the probe of the sensor as the electrolyte level drops.

The method 700 may further include, at block 708, measuring a depth from the aperture to the plate structure of the cell that should remain immersed in the liquid electrolyte of the cell and, at block 708, trimming the length of a probe of the combined temperature and liquid electrolyte sensor to a length less than the measured depth of the plate structure. As a result, the trimmed length will correlate with a depth of liquid electrolyte at which the battery still functions, but below which refilling of the electrolyte is desirable. Accordingly, the liquid detection of the sensor may prompt a user to refill the battery cell with electrolyte without losing function of the battery. In other embodiments, the depth of the plate structure may be known, and the probe may be trimmed based on that known depth.

The method 700 may further include, at block 712, inserting the probe of the combined temperature and liquid electrolyte sensor into the aperture in the cell, such that the probe is disposed in the liquid electrolyte of the battery cell and the tip of the probe is at a depth at which the battery cell still functions, but below which refilling of the electrolyte is desirable. The probe may be inserted so that a gasket of the sensor forms a fluid-tight seal in the aperture and/or so that a planar surface of the sensor is flush with the surface of the cell in which the aperture was formed.

While this disclosure has described certain embodiments, it will be understood that the claims are not intended to be limited to these embodiments except as explicitly recited in the claims. On the contrary, the instant disclosure is intended to cover alternatives, modifications and equivalents, which may be included within the spirit and scope of the disclosure. Furthermore, in the detailed description of the present disclosure, numerous specific details are set forth in order to provide a thorough understanding of the disclosed embodiments. However, it will be obvious to one of ordinary skill in the art that systems and methods consistent with this disclosure may be practiced without these specific details. In other instances, well known methods, procedures, components, and circuits have not been described in detail as not to unnecessarily obscure various aspects of the present disclosure.

Some portions of the detailed descriptions of this disclosure have been presented in terms of procedures, logic blocks, processing, and other symbolic representations of operations on data bits within a computer or digital system memory. These descriptions and representations are the means used by those skilled in the data processing arts to most effectively convey the substance of their work to others skilled in the art. A procedure, logic block, process, etc., is herein, and generally, conceived to be a self-consistent sequence of steps or instructions leading to a desired result. The steps are those requiring physical manipulations of physical quantities. Usually, though not necessarily, these physical manipulations take the form of electrical or magnetic data capable of being stored, transferred, combined, compared, and otherwise manipulated in a computer system or similar electronic computing device. For reasons of convenience, and with reference to common usage, such data is referred to as bits, values, elements, symbols, characters, terms, numbers, or the like, with reference to various presently disclosed embodiments. It should be borne in mind, however, that these terms are to be interpreted as referencing physical manipulations and quantities and are merely convenient labels that should be interpreted further in view of terms commonly used in the art. Unless specifically stated otherwise, as apparent from the discussion herein, it is understood that throughout discussions of the present embodiment, discussions utilizing terms such as “determining” or “outputting” or “transmitting” or “recording” or “locating” or “storing” or “displaying” or “receiving” or “recognizing” or “utilizing” or “generating” or “providing” or “accessing” or “checking” or “notifying” or “delivering” or the like, refer to the action and processes of a computer system, or similar electronic computing device, that manipulates and transforms data. The data is represented as physical (electronic) quantities within the computer system's registers and memories and is transformed into other data similarly represented as physical quantities within the computer system memories or registers, or other such information storage, transmission, or display devices as described herein or otherwise understood to one of ordinary skill in the art.

What is claimed is:

1. A sensor comprising:
a probe that is electrically conductive and thermally conductive and configured to be disposed in an electrically-conductive liquid;
a thermal coupler coupled to the probe;
a temperature determination circuit electrically coupled to the probe and configured to output a signal indicative of a temperature of the probe; and
a fluid detection circuit electrically coupled to the thermal coupler and configured to output a signal indicative of a presence of the liquid on the probe.

2. The sensor of claim 1, further comprising a printed circuit board (PCB), wherein the temperature determination circuit and the fluid detection circuit are on the PCB.

3. The sensor of claim 2, further comprising an overmolded body, wherein the probe extends from the body, wherein the PCB is disposed within the body.

4. The sensor of claim 1, wherein the thermal coupler comprises a sleeve crimped to the probe.

5. The sensor of claim 4, wherein the sleeve comprises copper.

6. The sensor of claim 1, wherein the temperature detection circuit is electrically isolated from the fluid detection circuit.

7. A battery comprising:
a battery cell comprising a cell body and a liquid electrolyte disposed in the cell body, the cell body defining an aperture;
a sensor comprising:
a probe that is electrically conductive and thermally conductive, the probe extending through the aperture and configured to be disposed in the liquid electrolyte;
a thermal coupler coupled to the probe;
a temperature determination circuit electrically coupled to the probe and configured to output a signal indicative of a temperature of the probe; and
a fluid detection circuit electrically coupled to the thermal coupler and configured to output a signal indicative of a presence of the liquid electrolyte on the probe.

8. The battery of claim 7, wherein the sensor further comprises a printed circuit board (PCB), wherein the temperature determination circuit and the fluid detection circuit are on the PCB.

9. The battery of claim 7, wherein the sensor further comprises an overmolded body, wherein the probe extends from the body, wherein the PCB is disposed within the body.

10. The battery of claim 7, wherein the thermal coupler comprises a sleeve crimped to the probe.

11. The battery of claim 10, wherein the sleeve comprises copper.

12. The battery of claim 7, wherein the temperature detection circuit is electrically isolated from the fluid detection circuit.

13. The battery of claim 7, wherein the sensor further comprises a gasket configured to form a fluid-tight seal with the aperture.

14. The battery of claim 7, wherein the battery cell is a lead-acid cell.

15. A battery system comprising:
a battery cell comprising a cell body and a liquid electrolyte disposed in the cell body, the cell body defining an aperture;
a sensor comprising:
a probe that is electrically conductive and thermally conductive, the probe extending through the aperture and configured to be disposed in the liquid electrolyte;
a thermal coupler coupled to the probe;
a temperature determination circuit electrically coupled to the probe and configured to output a signal indicative of a temperature of the probe; and
a fluid detection circuit electrically coupled to the thermal coupler and configured to output a signal indicative of a presence of the liquid electrolyte on the probe; and
an electronic battery monitor in electronic communication with the fluid detection circuit and with the temperature determination circuit and configured to:
determine a temperature of the probe according to the output of the temperature detection circuit;
determine a presence of liquid on the probe according to the output of the fluid detection circuit; and
output an alert when the battery monitor determines an absence of fluid on the probe or that the temperature of the probe exceeds a threshold.

16. The battery system of claim 15, wherein the electronic battery monitor comprises a display, a speaker, or a display and a speaker, configured to output the alert.

17. The battery system of claim 15, wherein the battery cell is a lead-acid cell.

18. The battery system of claim 15, wherein the sensor further comprises a printed circuit board (PCB), wherein the temperature determination circuit and the fluid detection circuit are on the PCB.

19. The battery system of claim 15, wherein the sensor further comprises an overmolded body, wherein the probe extends from the body, wherein the PCB is disposed within the body.

20. The battery system of claim 15, wherein the thermal coupler comprises a copper sleeve crimped to the probe.
